(19) United States
(12) Patent Application Publication
(10) Pub. No.: US 2005/0083121 A1
(43) Pub. Date: Apr. 21, 2005

(54) Trace-following powered amplifier

(75) Inventors: Ming Hor Tsai, Jhonghe City (TW); Ping Fong Ling, Tu-Chen (TW)

Correspondence Address: WILLIAM COLLARD;COLLARD & ROE, P.C., 1077 NORTHERN BOULEVARD, ROSLYN, NY, 11576, US

(73) Assignee: CHROMA ATE INC.

(21) Appl. No.: 10/813,290

(22) Filed: Mar. 30, 2004

(30) Foreign Application Priority Data
Oct. 15, 2003 (TW) 092128542

(51) Int. Cl. H03G 3/20

(52) U.S. Cl. 330/136

(57) ABSTRACT

The invention disclosed a trace following powered amplifier mainly used in solving the problem of circuit overheating caused by long test time, especially to an amplifier applicable to a low frequency and low distortion test apparatus such as a capacitor ripple current tester. The amplifier of present invention can make the most efficient use of electrical energy by incorporating a low frequency voltage peak value of an amplifier signal plus an estimated tolerance.

### FIELD OF THE INVENTION

The present invention relates to a power amplifier, especially to a circuit incorporated with a low frequency signal peak-value sampling circuit so that the power's voltage supplied to the amplifier varies with a small margin level of the amplifier's output amplitude, in order to make more efficiency and reduce the heat generated inside of the power amplifier.

### DESCRIPTION OF THE PRIOR ART

Conventional low distortion AC amplifier adapted only power source by a circuit with constant voltage stability, since what source thereto is a voltage of fixed magnitude; the loss is significant when an amplifier output smaller voltage amplitude and loading a larger current is needed. Although a method of pulse-width modulation (PWM) or cascade-increasing is developed by changing the pulse width of working signal to improve the efficiency, there is still disadvantage of increased relative distortion so that it is applicable only to AC voltage power supply.

The design of an ordinary power amplifier adapts a method supplied by a fixed power supply; the waveform of the power supply is shown as FIG. 4, which is a conventional power supply with fixed voltage. In the conventional method of power supply, the voltage does not change as the output amplitude of a machine changed, instead the voltage is held at a constant magnitude (in FIG. 4, the voltage of the power supply is assumed to be 12 volts), the larger shadow area A, which represents the power loss, the more power consumed in said machine and results in extra consumption of the output power.

In view of above ineffectiveness, the inventors have developed a trace-following powered amplifier capable of solving problems encountered in the design of Capacitor Ripple Current Tester, involving the transmission of high frequency/large current after intensive investigation into the problem.

### SUMMARY OF THE INVENTION

An object of the present invention is to provide a trace-following powered amplifier capable of performing a voltage peak-value sampling by changing the voltage amplitude of power supply in accordance with the output voltage amplitude of a test apparatus so as to make effective use of its power output.

Another object of the present invention is to provide a trace-following powered amplifier capable of conserving the long term, usually more than two months, bum-in power consumption to accommodate the customer's requirement for extending lifetime of a test apparatus.

For achieving above objects, according to the present invention, a trace-following powered amplifier is provided, comprising a signal sampling circuit, a power supply, and an amplifier, wherein the signal sampling circuit is provided for sampling a voltage peak value which is obtained from a signal output end of a test instrument and sending the sampled signal to an input end of the power supply, the power supply is provided between the signal sampling circuit and the amplifier which provides a trace following voltage signal having a tolerance after sampling to the amplifier; and the amplifier is provided for changing its output signal following an output amplitude feedback, thus a the voltage supplies signal from the power supply is controlled to be equivalent to the peak-value of signal of the amplifier plus an estimated tolerance the output so as to make most efficient use of electrical energy and to make best use of power.

### BRIEF DESCRIPTION OF DRAWINGS

FIG. 1 is a circuit block diagram of the present invention.

FIG. 2 is a schematic circuit diagram of a trace following powered amplifier of the present invention.

FIG. 3 is a diagram showing test data measured by the circuit as shown in FIG. 2.

FIG. 4 is a diagram showing test data measured by the conventional method under constant power supply.

### DETAILED DESCRIPTION OF THE INVENTION

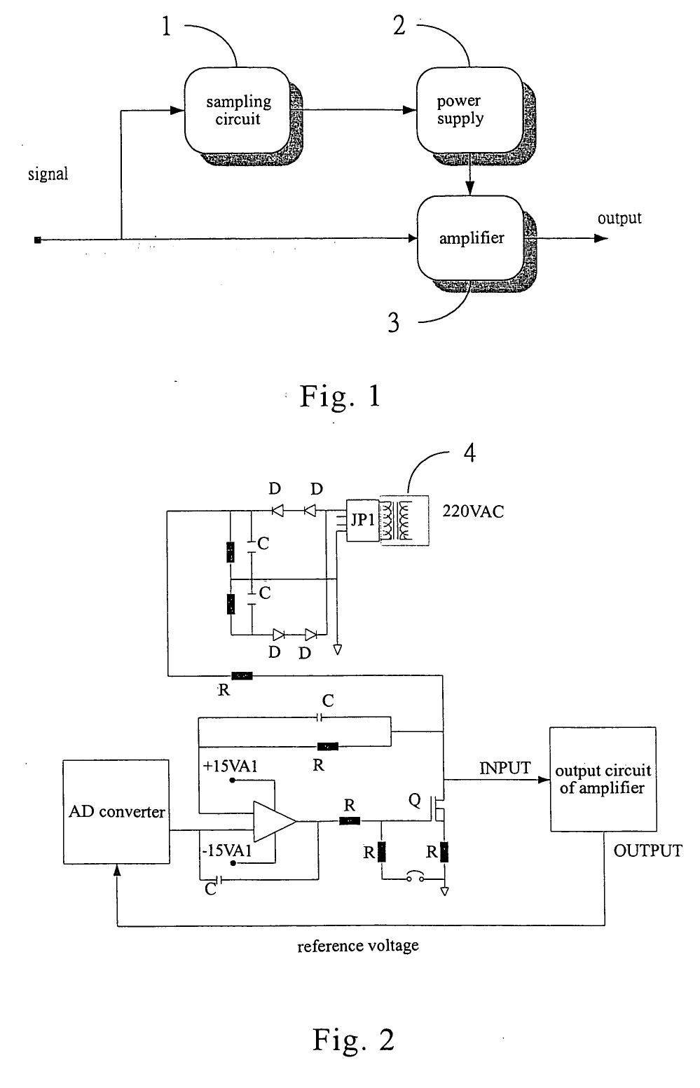

The signal peak value sampling function of the present invention varies the power supply output rate in accordance with the output amplitude of a test apparatus by feedback the maximum output signal of amplifier and then to restrict the output amplitude of power supply. More details are given by referring to FIG. 1.

FIG. 1 is a circuit block diagram showing the circuit of the present invention which comprises: a sampling circuit 1 for sampling a signal peak value that from the output end of a signal source and sending the same signal to the input end of the power supply, the purpose of providing such circuit is to restrict the voltage supplied from power supply to the peak value of an amplifier signal plus an estimated tolerance, as described above; a power supply 2 connecting between the signal sampling circuit and the amplifier responsible for supplying voltage to the amplifier, in which the voltage amplitude of the power supply varies as the feedback of the output terminal signal changed, thus a trace following voltage with tolerance is supplied to the amplifier after sampling; and an amplifier 3 for changing the output signal in accordance with the output amplitude of the feedback.

FIG. 2 is a circuit diagram showing the circuit of the present invention. By inputting to the primary side of a transformer 4, a 220V AC voltage is subject to voltage multiplication and rectification before sending a power signal to the drain electrode of a transistor Q, it is then possible to change the amplitude of voltage output from the drain electrode of the transistor Q via the variation of a control signal output from a comparator.

Also, the amplifier will first perform rectification/filtering processing on the output signal and then feedback the processed output signal to an A/D converter when the output signal changed. Once receiving the signal and the detection of change on the signal, said A/D converter will emit a variable control signal to change the output of said comparator and in turn the power supply, it is then possible to supply a voltage with amplitude of the peak value of an amplifier signal plus an estimated tolerance so as to make the most efficient use of the electrical energy and to make the best use of power.

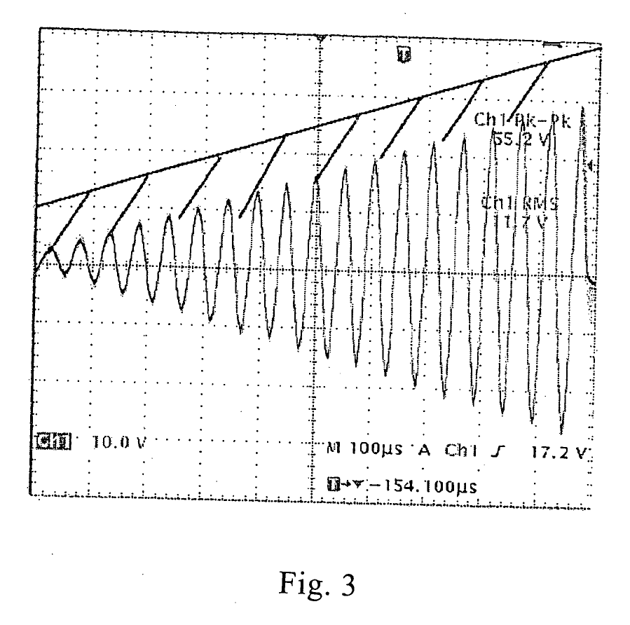

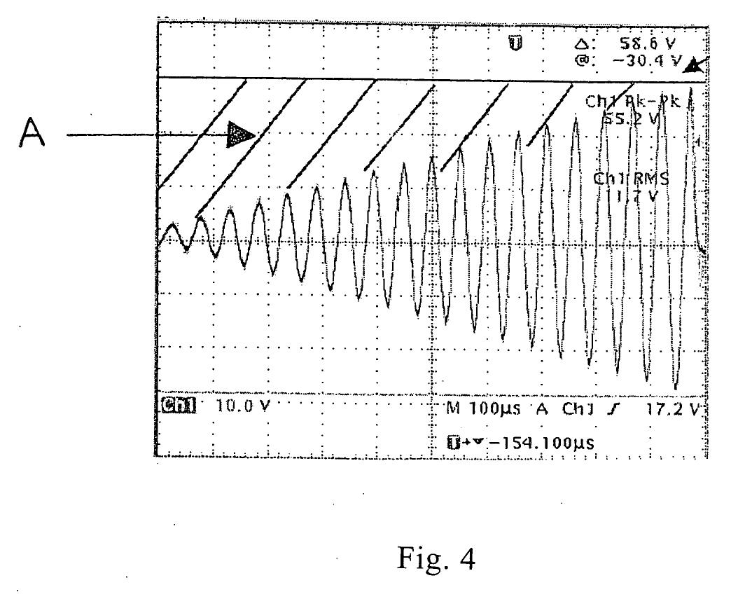

The sampling function of present invention is given by referring to FIG. 3. Have the voltage supplied to said amplifier varies as the amplitude of voltage outputted from said test apparatus while achieving a good trace following powered mode so as to greatly reduce the inefficient use of power and reduce the heating problem generated in the test apparatus.

The present invention can also resolve the following problems:
1. Customized requirement can be achieved.
2. After reducing the heating problem, it is possible to extend the performance of each related component and in turn prolong the service lifetime of the test apparatus.

It should be understood that present invention is not limited to above description made to one of the preferred embodiments and equivalent changes and modifications of the present invention are considered to fall within claims as follows:

List of Reference Numerals

| Numeral | Elements |
|---|---|
| 1. | Sampling circuit |
| 2. | Power supply |
| 3. | Amplifier |
| 4. | Transformer |

1. A trace-following powered amplifier, comprising: a signal sampling circuit, a power supply, and an amplifier, wherein said signal sampling circuit is provided for sampling a peak-value from a signal which is obtained from a signal output end of a test instrument and sending the sampled signal to an input end of said power supply, said power supply is provided between said signal sampling circuit and said amplifier while provides a trace-following voltage signal having a tolerance after sampling to said amplifier; and an amplifier is provided for changing its output signal following an output amplitude feedback, thus a voltage supplied signal from said power supply is controlled to be equivalent to the peak-value of signal of said amplifier plus an estimated tolerance so as to make most efficient use of electrical energy and to make best use of power.

2. The trace following powered amplifier as set forth in claim 1, in which the output signal of the power supply is subject to voltage multiplication and rectification through a transformer before sending a power source to one terminal of a transistor, it then changes an amplitude of voltage outputted from the other terminal of the transistor via the variation of a control signal outputted from a comparator.

3. The trace following powered amplifier as set forth in claim 1, in which said amplifier performs rectification/filtering processing on the output signal thereof and then feedbacks the processed output signal to an A/D converter when the output signal changed, while said A/D converter emit a variable control signal to change the output of said comparator once receiving said signal and the detection of change on the signal.
